(19) United States
(12) Patent Application Publication
(10) Pub. No.: US 2010/0244146 A1
(43) Pub. Date: Sep. 30, 2010

(54) SEMICONDUCTOR DEVICE AND METHOD OF MANUFACTURING THE SAME

(75) Inventor: Hirohiko Uno, Kanagawa (JP)

Correspondence Address: YOUNG & THOMPSON, 209 Madison Street, Suite 500, Alexandria, VA, 22314, US

(73) Assignee: NEC ELECTRONICS CORPORATION, Kanagawa (JP)

(21) Appl. No.: 12/727,403

(22) Filed: Mar. 19, 2010

(30) Foreign Application Priority Data
Mar. 31, 2009 (JP) 2009-084784

(51) Int. Cl. H01L 23/48

(52) U.S. Cl. 257/401; 257/288; 257/734; 257/E23.01

(57) ABSTRACT

Provided are a semiconductor device capable of reducing a difference in wiring resistance between paths from a gate pad to a gate electrode and capable of applying a gate voltage to the gate electrode more uniformly, and a method of manufacturing the semiconductor device. The semiconductor device according to an exemplary aspect of the present invention includes a gate pad supplied with a gate voltage applied to a gate electrode of each MOSFET cell disposed in an active region, a gate connection line connected to the gate pad, and a plurality of gate lead-out lines connected in parallel between the gate electrode and the gate connection line. Each of the plurality of gate lead-out lines has a resistance value that becomes smaller by every one or plural gate lead-out lines as the gate lead-out lines are located farther away from the gate pad.

### INCORPORATION BY REFERENCE

This application is based upon and claims the benefit of priority from Japanese patent application No. 2009-84784, filed on Mar. 31, 2009, the disclosure of which is incorporated herein in its entirety by reference.

### BACKGROUND

1. Field of the Invention

The present invention relates to a semiconductor device and a method of manufacturing the same.

2. Description of Related Art

Semiconductor devices including power metal-oxide-semiconductor field-effect transistors (MOSFETs) generally have an active region in which a large number of vertical-type MOSFETs are arranged. The large number of vertical-type MOSFETs are separated by a gate electrode shaped like a lattice. Outside the active region, gate lead-out lines made of polysilicon, for example, are formed to lead out the gate electrode. The gate lead-out lines are formed continuously and integrally with the gate electrodes, and function as a part of a gate resistance (see Japanese Unexamined Patent Application Publication Nos. 2005-322949, 2004-259981, 2007-67249, 2004-79955, and 2003-258254).

Further, there has been proposed a technique for increasing a gate withstand voltage in order to secure high reliability in such semiconductor devices. Japanese Unexamined Patent Application Publication No. 2005-322949 discloses a technique for improving the gate withstand voltage by changing the thickness of an insulating film. Furthermore, Japanese Unexamined Patent Application Publication Nos. 2004-259981 and 2007-67249 disclose a technique for improving the gate withstand voltage depending on the configuration and layout of a gate electrode and a gate line.

Japanese Unexamined Patent Application Publication No. 2004-79955 proposes a configuration capable of improving the gate withstand voltage and suppressing a local on-resistance by forming MOSFET cells into a hexagonal shape in view of the crystal orientation of silicon. Moreover, Japanese Unexamined Patent Application Publication No. 2003-258254 proposes a configuration for reducing the wiring resistance of a gate electrode by, for example, increasing a contact area of the gate electrode.

A description is now given of the configuration of a typical semiconductor device in which a large number of MOSFETs are arranged. FIG. 10 is a top view showing the typical semiconductor device in which a large number of MOSFET cells are arranged. Referring to FIG. 10, in the semiconductor device, a source electrode 110 made of aluminum is disposed to cover an active region which occupies a central portion.

In an outer peripheral region of the semiconductor device, there is disposed a gate metal line 111 which extends from a gate pad GP2 to surround the source electrode 110 and which is made of aluminum, for example. A gate lead-out line region 170, in which gate lead-out lines described later are formed, is disposed between the source electrode 110 and the gate metal line 111.

FIG. 11 is a top view of a region E101 shown in FIG. 10. Referring to FIG. 11, in the active region, MOSFET cells 120, which are vertical-type N-channel MOSFETs having a trench gate structure, are arranged in a staggered manner. In a region between the MOSFET cells 120, a gate electrode 106 made of polysilicon is formed. In the outer peripheral region, a gate connection line 108 made of polysilicon is formed. The gate metal line 111 is formed and superimposed on the gate connection line 108. Furthermore, gate lead-out lines 171, which are made of polysilicon and have a uniform interval therebetween, a uniform width, and a uniform length, are formed between the gate electrode 106 and the gate connection line 108.

Next, the cross-sectional structure of the semiconductor device will be described. FIG. 12A is a cross-sectional view taken along the line IIA-IIA of FIG. 11, and FIG. 12B is a cross-sectional view taken along the line IIB-IIB of FIG. 11.

In the active region of the cross section shown in FIG. 12A, an n-type drain layer 102 and a p-type channel layer 103 are stacked in this order on an n⁺-type substrate 101. Trenches TR2 formed in the active region are each covered with a gate oxide film 104. At both ends of the opening of each of the trenches TR2, n⁺-type source regions 105 are formed. The gate electrode 106 and an interlayer insulating film 109 are formed in this order on each of the trenches TR2. An upper portion of the active region is covered with the source electrode 110.

Meanwhile, in the outer peripheral region, the n-type drain layer 102 and the p-type channel layer 103 are stacked in this order on the n+-type substrate 101. The gate oxide film 104 is formed on the p-type channel layer 103. The gate connection line 108 made of polysilicon is formed on the gate oxide film 104. The interlayer insulating film 109 having an opening 109a is formed on the gate connection line 108. The gate metal line 111 made of aluminum is connected to the gate connection line 108 through the opening 109a.

In the active region of the cross section shown in FIG. 12B, the n-type drain layer 102 is stacked on the n+-type substrate 101. The gate oxide film 104 is formed on the n-type drain layer 102. The gate electrode 106, which is made of polysilicon, the interlayer insulating film 109, and the source electrode 110 are formed in this order on the gate oxide film 104.

Meanwhile, in the outer peripheral region, the n-type drain layer 102 is stacked on the n⁺-type substrate 101. The p-type channel layer 103 is partially stacked on the n-type drain layer 102. The n-type drain layer 102 and the p-type channel layer 103 are covered with the gate oxide film 104. The gate connection line 108 made of polysilicon is formed on the gate oxide film 104 and connected to the gate electrode 106, which is formed in the active region, through the gate lead-out line 171 made of polysilicon. The interlayer insulating film 109 having the opening 109a is formed on the gate connection line 108. The gate metal line 111 made of aluminum is connected to the gate connection line 108 through the opening 109a.

In the semiconductor device, a gate voltage supplied to the gate pad GP2 is applied to the gate electrode 106 of each of the MOSFET cells 120 through the gate metal line 111 made of aluminum and through the gate connection line 108 and the gate lead-out lines 171 which are made of polysilicon.

Thus, in the semiconductor device, the gate connection line 108 and the gate metal line 111 are arranged to surround the active region so that the gate voltage is applied to the gate electrode 106 of each of the MOSFET cells 120 as uniformly as possible.

### SUMMARY

The present inventor has recognized that further improvement is necessary, as described below. The gate lead-out lines 171 and the gate connection line 108, which are made of polysilicon, have an electrical resistance which is too large to be neglected as compared with the gate metal line 111 made of aluminum.

FIG. 13 is a perspective view schematically showing the semiconductor device shown in FIG. 10. As described above, the gate voltage supplied to the gate pad GP2 is applied to the gate electrode 106 (not shown in FIG. 13) of each of the MOSFET cells 120, which is formed in the active region covered with the source electrode 110, through the gate metal line 111 (not shown in FIG. 13) made of aluminum and through the gate connection line 108 and the gate lead-out lines 171 which are made of polysilicon.

Accordingly, a wiring resistance Rw of a polysilicon line from the gate pad GP2 to a given gate lead-out line 171an is equal to the sum of a resistance Rb of the gate connection line 108 and a resistance Ra of the gate lead-out line 171an (Rw=Ra+Rb).

The resistance Rb of the gate connection line 108 increases as a wiring distance h from the gate pad GP2 increases, which causes a difference in resistance between a path located at a position near the gate pad GP2 and a path located at a position far apart from the gate pad GP2.

Meanwhile, the resistance Ra of each of the gate lead-out lines 171 is constant, since the gate lead-out lines 171 have a uniform length.

In other words, the wiring resistance of the semiconductor device varies between paths depending on the distance from the gate pad GP2. This makes it impossible to uniformly apply the gate voltage to the gate electrode 106 formed in the active region.

A first exemplary aspect of the present invention is a semiconductor device including a gate pad supplied with a gate voltage applied to a gate electrode of a field-effect transistor disposed in an active region, a gate connection line connected to the gate pad, and a plurality of gate lead-out lines connected in parallel between the gate electrode and the gate connection line. In the semiconductor device, each of the plurality of gate lead-out lines has a resistance value that becomes smaller by every one or plural gate lead-out lines as the gate lead-out lines are located farther away from the gate pad.

According to the semiconductor device of the first exemplary aspect of the present invention, a substantial wiring resistance of a gate lead-out line located at a position far apart from the gate pad can be reduced. As a result, the difference in the wiring resistance between paths from the gate pad to the gate electrode is reduced, which makes it possible to apply the gate voltage to the gate electrode more uniformly. That is, it is possible to provide a semiconductor device capable of reducing the difference in the wiring resistance between paths from the gate pad to the gate electrode and capable of applying the gate voltage to the gate electrode more uniformly.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a top view showing a semiconductor device according to a first exemplary embodiment of the present invention;

FIG. 2A is a partially enlarged view showing the semiconductor device according to the first exemplary embodiment;

FIG. 2B is a partially enlarged view showing the semiconductor device according to the first exemplary embodiment;

FIG. 2C is a partially enlarged view showing the semiconductor device according to the first exemplary embodiment;

FIG. 3A is a cross-sectional view showing the semiconductor device according to the first exemplary embodiment;

FIG. 3B is a cross-sectional view showing the semiconductor device according to the first exemplary embodiment;

FIG. 4 is a top view showing a semiconductor device according to a second exemplary embodiment of the present invention;

FIG. 5A is a partially enlarged view showing the semiconductor device according to the second exemplary embodiment;

FIG. 5B is a partially enlarged view showing the semiconductor device according to the second exemplary embodiment;

FIG. 5C is a partially enlarged view showing the semiconductor device according to the second exemplary embodiment;

FIG. 6 is a top view showing a semiconductor device according to a third exemplary embodiment of the present invention;

FIG. 7A is a partially enlarged view showing the semiconductor device according to the third exemplary embodiment;

FIG. 7B is a partially enlarged view showing the semiconductor device according to the third exemplary embodiment;

FIG. 7C is a partially enlarged view showing the semiconductor device according to the third exemplary embodiment;

FIG. 8 is a top view showing a semiconductor device according to a fourth exemplary embodiment of the present invention;

FIG. 9A is a partially enlarged view showing the semiconductor device according to the fourth exemplary embodiment;

FIG. 9B is a partially enlarged view showing the semiconductor device according to the fourth exemplary embodiment;

FIG. 9C is a partially enlarged view showing the semiconductor device according to the fourth exemplary embodiment;

FIG. 10 is a top view showing a typical semiconductor device;

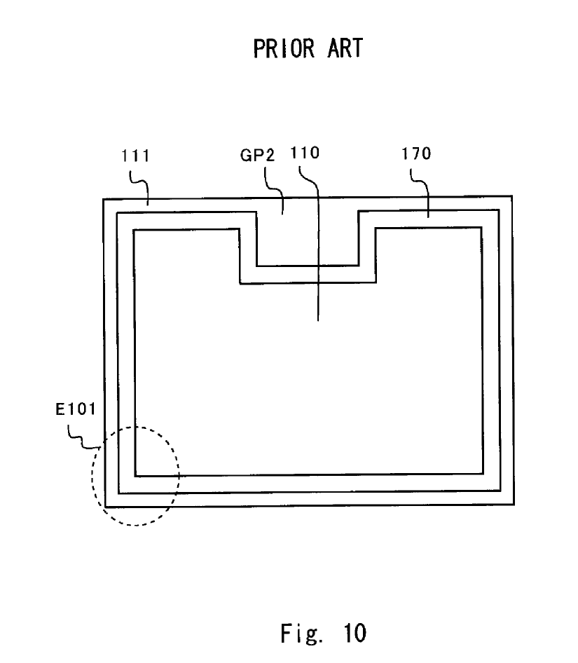

FIG. 11 is a partially enlarged view showing the typical semiconductor device;

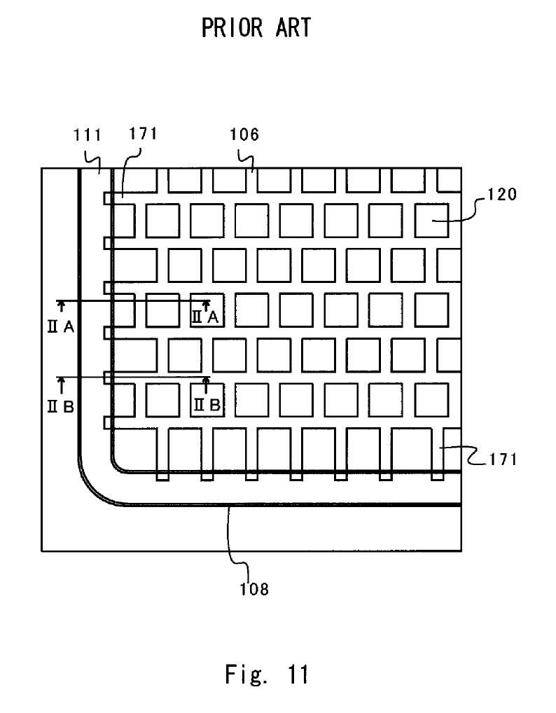

FIG. 12A is a cross-sectional view showing the typical semiconductor device;

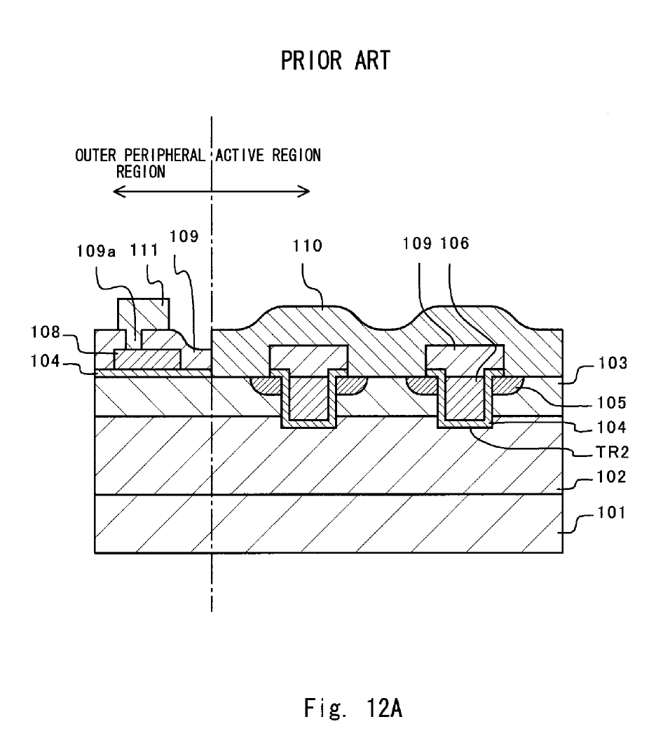

FIG. 12B is a cross-sectional view showing the typical semiconductor device; and

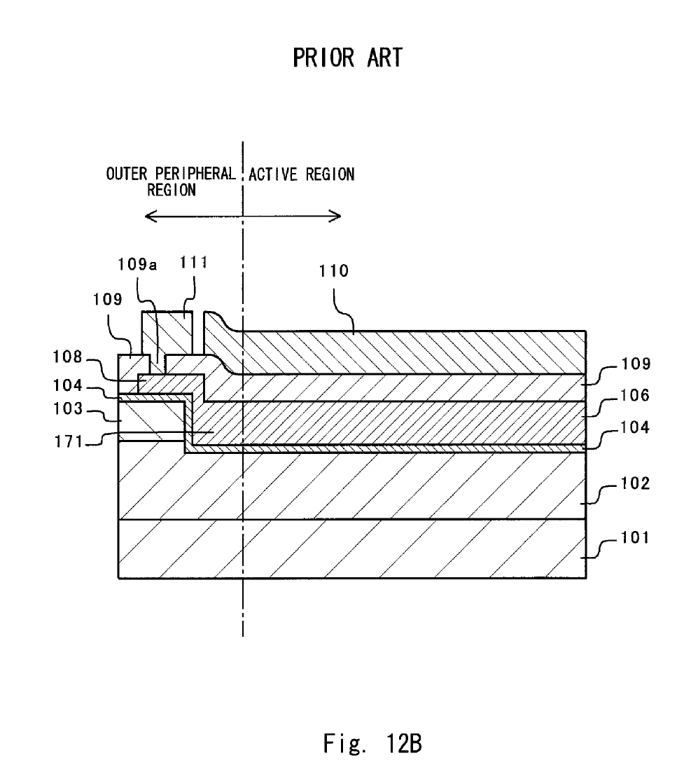

FIG. 13 is a perspective view showing the typical semiconductor device.

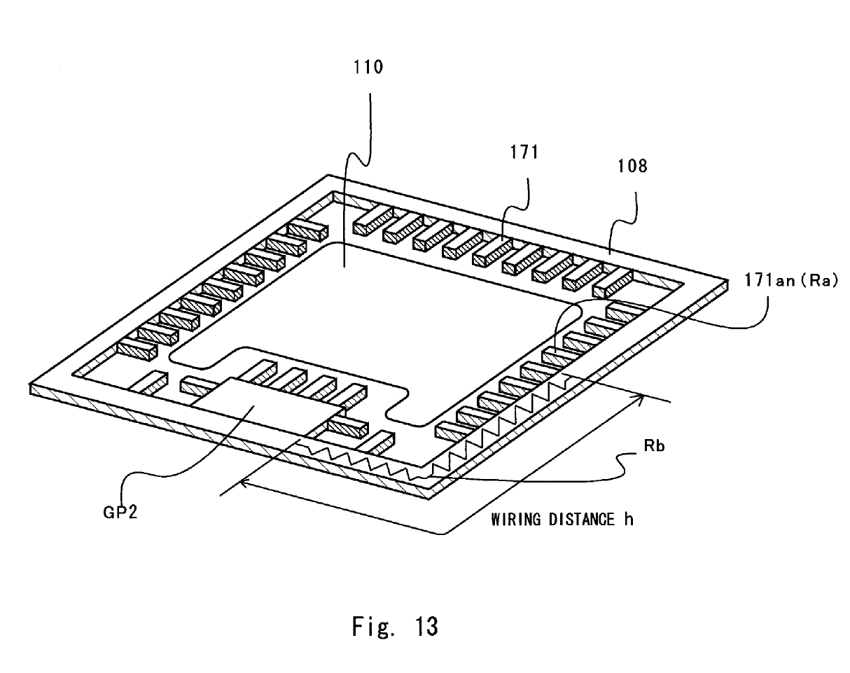

### DETAILED DESCRIPTION OF THE EXEMPLARY EMBODIMENTS

### First Exemplary Embodiment

An exemplary embodiment of the present invention will be described below with reference to the accompanying drawings.

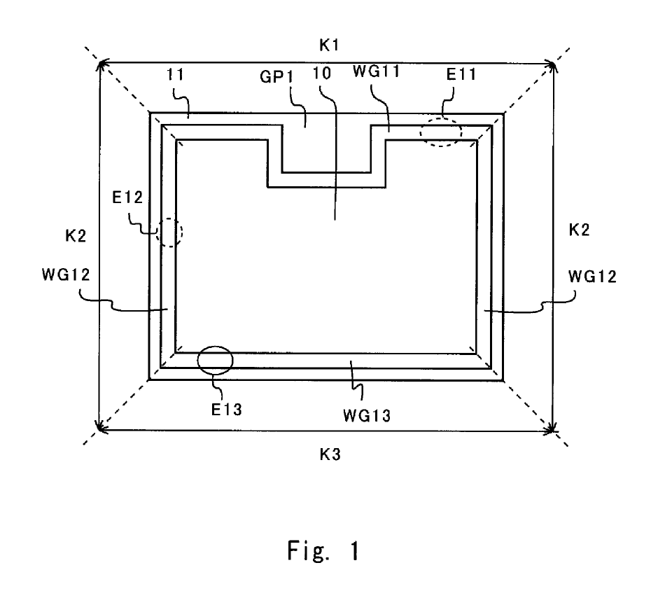

The configuration of a semiconductor device according to a first exemplary embodiment of the present invention will be described. FIG. 1 is a top view showing the semiconductor device. Referring to FIG. 1, in the semiconductor device, a source electrode 10 made of aluminum, for example, is formed to cover an active region which occupies a central portion.

In an outer peripheral region of the semiconductor device, there is formed a gate metal line 11 which extends from a gate pad GP1 to surround the source electrode 10 which is made of aluminum, for example. The outer peripheral region is divided into sections K1 to K3 which are arranged in ascending order of distance from the gate pad GP1. In the section K1, a gate lead-out line group WG11 is formed between the source electrode 10 and the gate metal line 11. In the section K2, a gate lead-out line group WG12 is formed between the source electrode 10 and the gate metal line 11. In the section K3, a gate lead-out line group WG13 is formed between the source electrode 10 and the gate metal line 11.

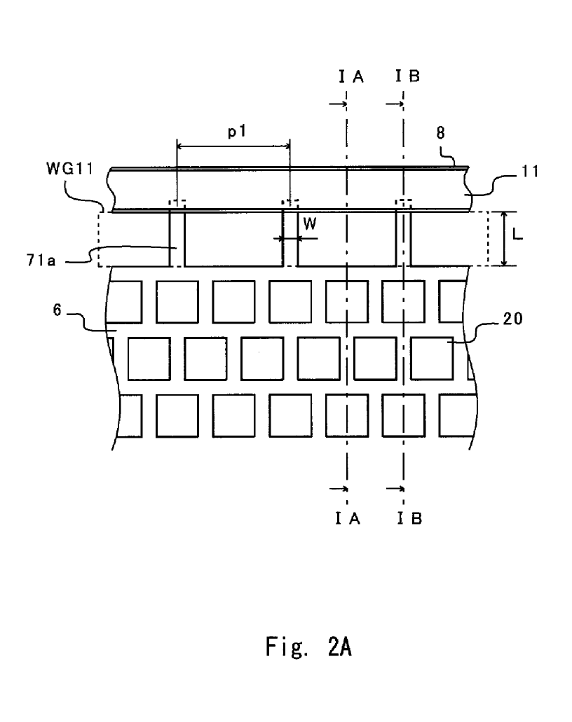

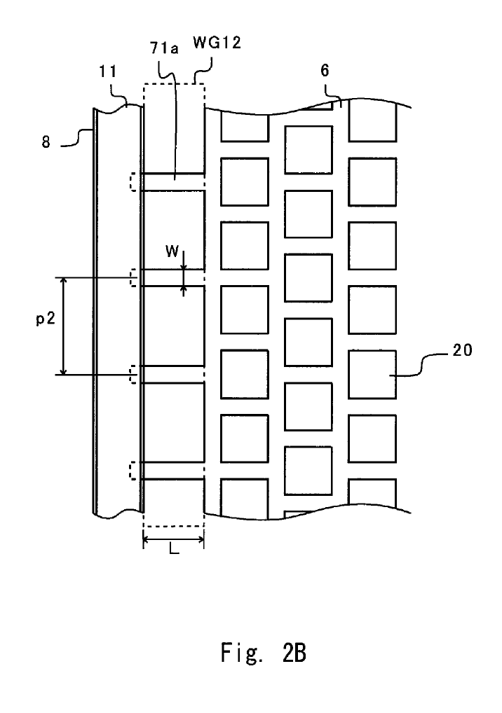

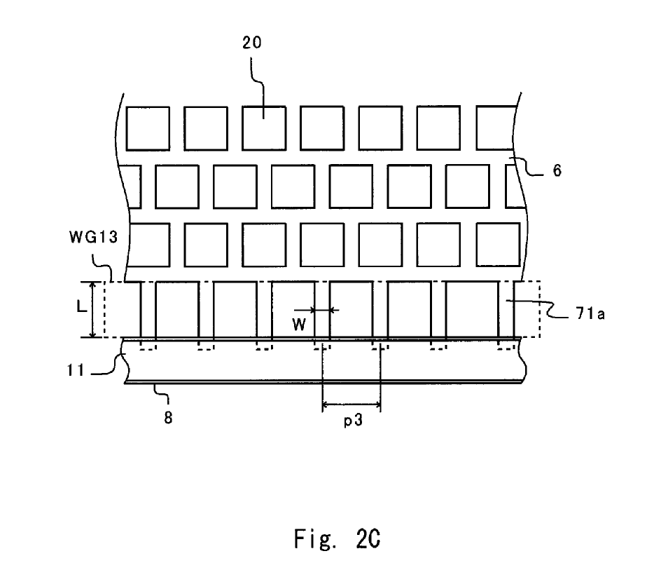

FIG. 2A is a top view of a region E11 shown in FIG. 1. Referring to FIG. 2A, in the active region, a large number of MOSFET cells 20, which are vertical-type N-channel MOSFETs having a trench gate structure, are arranged in a staggered manner. In a region between the MOSFET cells 20, there is formed a gate electrode 6 made of polysilicon. In the outer peripheral region, there is formed a gate connection line 8 made of polysilicon. The gate metal line 11 is formed and superimposed on the gate connection line 8. In the gate lead-out line group WG11 between the gate electrode 6 and the gate connection line 8, gate lead-out lines 71a which have an arrangement pitch p1, a width W, and a length L and are made of polysilicon, are formed to extend to a portion below the gate connection line 8.

FIG. 2B is a top view of a region E12 shown in FIG. 1. Referring to FIG. 2B, in the gate lead-out line group WG12, the gate lead-out lines 71a are formed at an arrangement pitch p2. The other configurations are similar to those shown in FIG. 2A, so the description thereof is omitted.

FIG. 2C is a top view of a region E13 shown in FIG. 1. Referring to FIG. 2C, in the gate lead-out line group WG13, the gate lead-out lines 71a are formed at an arrangement pitch p3. The other configurations are similar to those shown in FIG. 2A, so the description thereof is omitted.

In order to lower the electrical resistance, impurities are introduced into the gate electrode 6, the gate lead-out lines 71a, and the gate connection line 8 with an impurity concentration D.

In this configuration, the gate lead-out lines 71a have a uniform width W, a uniform length L, and a uniform impurity concentration D, while the arrangement pitches p1 to p3 in the gate lead-out line groups WG11 to WG13 differ from each other and are set to satisfy p1>p2>p3.

Specifically, in this configuration, p1:p2:p3=4:3:2 is satisfied. Note that the source electrode 10 that covers the active region is not shown in FIGS. 2A to 2C so as to facilitate the explanation of the configuration of the active region.

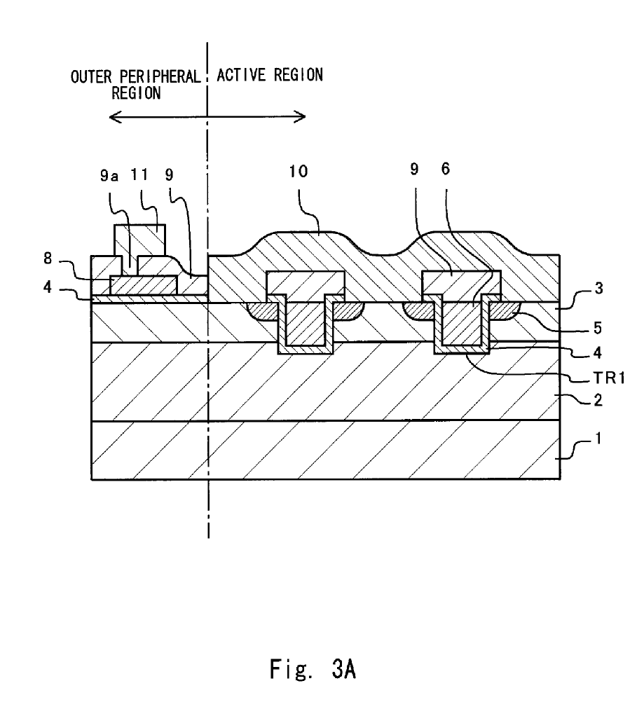

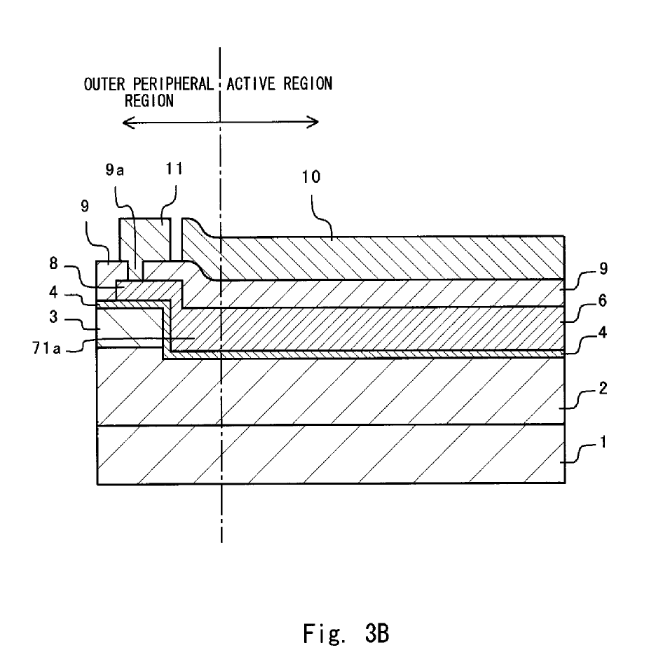

Next, the cross-sectional structure of the semiconductor device will be described. FIG. 3A is a cross-sectional view taken along the line IA-IA of FIG. 2A, and FIG. 3B is a cross-sectional view taken along the line IB-IB of FIG. 2A.

In the active region of the cross section shown in FIG. 3A, an n-type drain layer 2 and a p-type channel layer 3 are stacked in this order on an n⁺-type substrate 1. Trenches TR1 formed in the active region are each covered with a gate oxide film 4. At both ends of the opening of each of the trenches TR1, n⁺-type source regions 5 are formed. The gate electrode 6 and an interlayer insulating film 9 are formed in this order on each of the trenches TR1. An upper portion of the active region is covered with the source electrode 10.

Meanwhile, in the outer peripheral region, the n-type drain layer 2 and the p-type channel layer 3 are stacked in this order on the n⁺-type substrate 1. The gate oxide film 4 is formed on the p-type channel layer 3. The gate connection line 8 made of polysilicon is formed on the gate oxide film 4. The interlayer insulating film 9 having an opening 9a is formed on the gate connection line 8. The gate metal line 11 made of aluminum is connected to the gate connection line 8 through the opening 9a.

In the active region of the cross section shown in FIG. 3B, the n-type drain layer 2 is stacked on the n⁺-type substrate 1. The gate oxide film 4 is formed on the n-type drain layer 2. The gate electrode 6, which is made of polysilicon, the interlayer insulating film 9, and the source electrode 10 are formed in this order on the gate oxide film 4.

Meanwhile, in the outer peripheral region, the p-type channel layer 3 is partially stacked on the n-type drain layer 2. The n-type drain layer 2 and the p-type channel layer 3 are covered with the gate oxide film 4. The gate connection line 8 made of polysilicon is formed on the gate oxide film 4 and connected to the gate electrode 6, which is formed in the active region, through the gate lead-out line 71a made of polysilicon. The interlayer insulating film 9 having the opening 9a is formed on the gate connection line 8. The gate metal line 11 made of aluminum is connected to the gate connection line 8 through the opening 9a.

In this configuration, the arrangement pitches of the gate lead-out lines 71a are set to satisfy p1>p2>p3. Accordingly, the gate lead-out lines 71a in the gate lead-out line group WG11, which is located near the gate pad GP1, are formed at low density. The gate lead-out lines 71a in the gate lead-out line group WG12 and the gate lead-out line group WG13 are formed at higher density as the distance from the gate pad GP1 increases.

Here, consideration is given to a wiring resistance in the outer peripheral region of the semiconductor device. As the gate lead-out line groups are located farther away from the gate pad GP1, the contribution of the gate connection line 8 to the wiring resistance in the gate lead-out line groups increases. Thus, the contribution of the gate connection line 8 in the gate lead-out line groups WG11 to WG13 is represented as (gate lead-out line group WG11)<(gate lead-out line group WG12)<(gate lead-out line group WG13).

Meanwhile, as the gate lead-out line groups are located farther away from the gate pad GP1, the gate lead-out lines 71a in the gate lead-out line groups are formed at higher density and a substantial current path cross-sectional area increases. Thus, the contribution of the gate lead-out lines 71a in the gate lead-out line groups WG11 to WG13 is represented as (gate lead-out line group WG11)>(gate lead-out line group WG12)>(gate lead-out line group WG13).

In other words, the magnitude relation between the contribution of the gate lead-out lines 71a and the contribution of the gate connection line 8 to the wiring resistance in the gate lead-out line groups WG11 to WG13 is reversed. Therefore, the difference in wiring resistance between paths in the gate lead-out line groups WG11 to WG13 can be reduced as compared with the case in which the gate lead-out lines 71a are formed at a uniform pitch. As a result, a gate voltage supplied to the gate pad GP1 can be more uniformly applied to the MOSFET cells 20 formed in the active region.

### Second Exemplary Embodiment

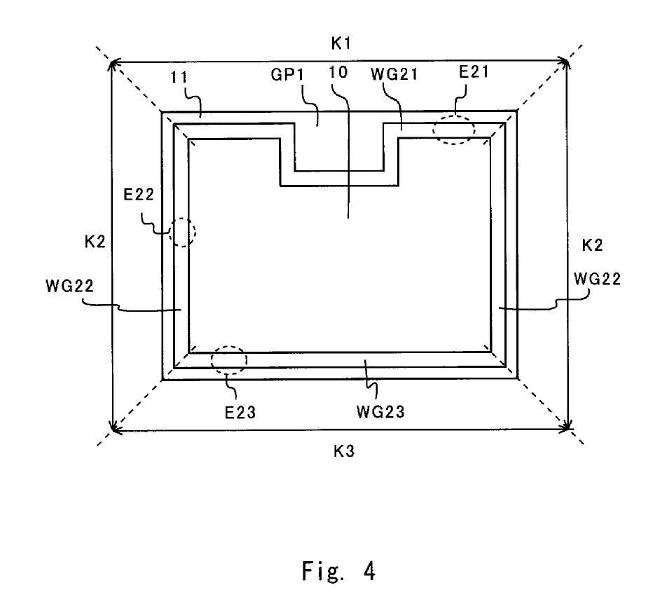

Next, the configuration of a semiconductor device according to a second exemplary embodiment of the present invention will be described. FIG. 4 is a top view showing the semiconductor device. Referring to FIG. 4, gate lead-out line groups WG21 to WG23 are formed between the source electrode 10 and the gate metal line 11. The other configurations are similar to those shown in FIG. 1, so the description thereof is omitted.

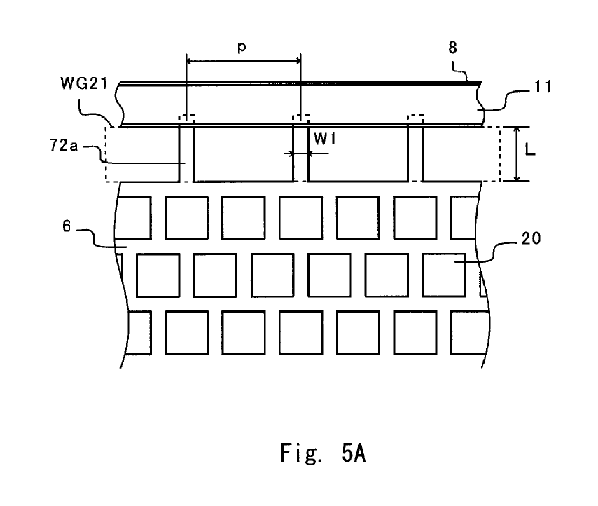

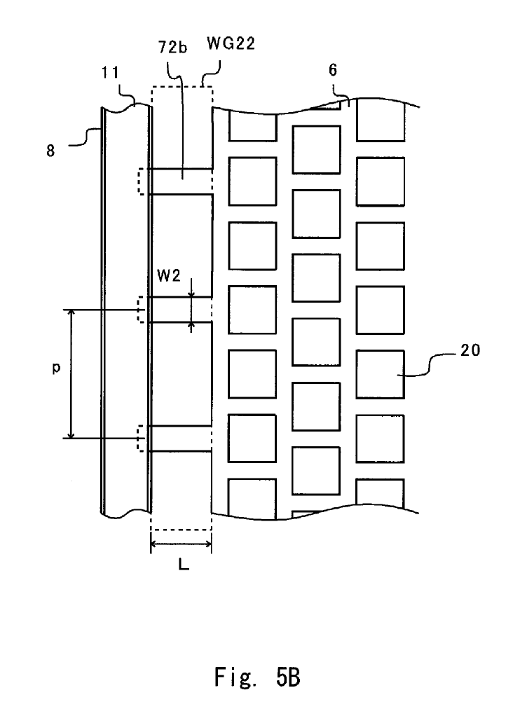

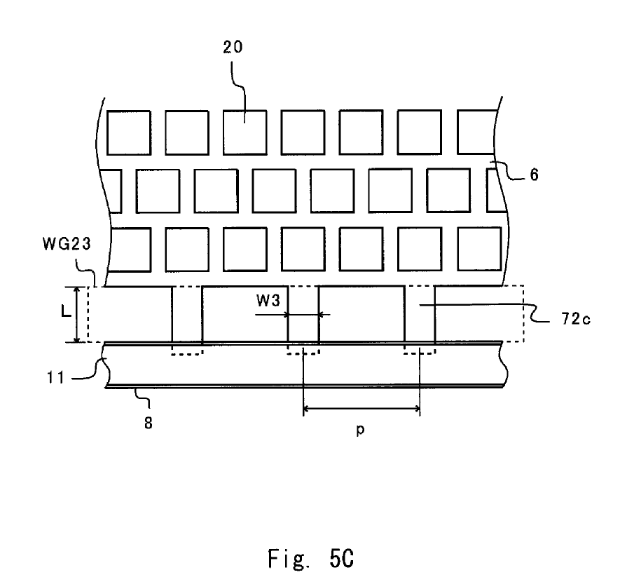

FIG. 5A is a top view of a region E21 shown in FIG. 4. Referring to FIG. 5A, in the gate lead-out line group WG21, gate lead-out lines 72a are formed with an arrangement pitch p, a width W1, and the length L. The other configurations are similar to those shown in FIG. 2A, so the description thereof is omitted.

FIG. 5B is a top view of a region E22 shown in FIG. 4. Referring to FIG. 5B, in the gate lead-out line group WG22, gate lead-out lines 72b are formed with a width W2. The other configurations are similar to those shown in FIG. 5A, so the description thereof is omitted.

FIG. 5C is a top view of a region E23 shown in FIG. 4. Referring to FIG. 5C, in the gate lead-out line group WG23, gate lead-out lines 72c are formed with a width W3. The other configurations are similar to those shown in FIG. 5A, so the description thereof is omitted.

In order to lower the electrical resistance, impurities are introduced into the gate electrode 6, the gate lead-out lines 72a to 72c, and the gate connection line 8 with the impurity concentration D.

In this configuration, the gate lead-out lines 72a to 72c have a uniform arrangement pitch p, a uniform length L, and a uniform impurity concentration D, while the widths W1 to W3 in the gate lead-out line groups WG21 to WG23 differ from each other and are set to satisfy W1<W2<W3. Specifically, in this configuration, W1:W2:W3=2:3:4 is satisfied.

Here, consideration is given to a wiring resistance in the outer peripheral region of the semiconductor device. As in the first exemplary embodiment, the contribution of the gate connection line 8 to the wiring resistance in the gate lead-out line groups WG21 to WG23 is represented as (gate lead-out line group WG21)<(gate lead-out line group WG22)<(gate lead-out line group WG23).

Meanwhile, as the gate lead-out line groups are located farther away from the gate pad GP1, the widths of the gate lead-out lines 72a to 72c in the gate lead-out line groups increase, and a substantial current path cross-sectional area increases and the electrical resistance decreases. Accordingly, the contribution of the gate lead-out lines 72a to 72c in the gate lead-out line groups WG21 to WG23 is represented as (gate lead-out line group WG21)>(gate lead-out line group WG22)>(gate lead-out line group WG23).

In other words, the magnitude relation between the contribution of the gate lead-out lines 72a to 72c and the contribution of the gate connection line 8 to the wiring resistance in the gate lead-out line groups WG21 to WG23 is reversed. Therefore, the difference in wiring resistance between paths in the gate lead-out line groups WG21 to WG23 can be reduced as compared with the case in which the gate lead-out lines 72a to 72c are formed with a uniform width. As a result, the gate voltage supplied to the gate pad GP1 can be more uniformly applied to the MOSFET cells 20 formed in the active region.

### Third Exemplary Embodiment

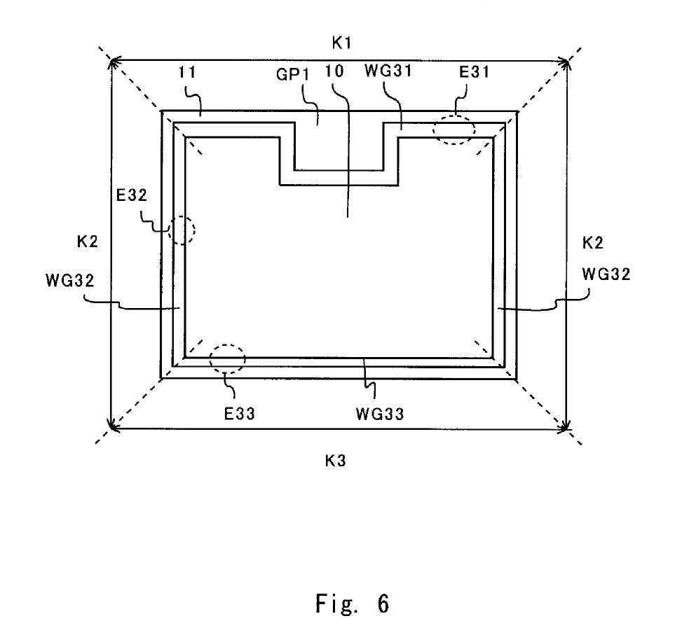

Next, the configuration of a semiconductor device according to a third exemplary embodiment of the present invention will be described. FIG. 6 is a top view showing the semiconductor device. Referring to FIG. 6, gate lead-out line groups WG31 to WG33 are formed between the source electrode 10 and the gate metal line 11. The other configurations are similar to those shown in FIG. 1, so the description thereof is omitted.

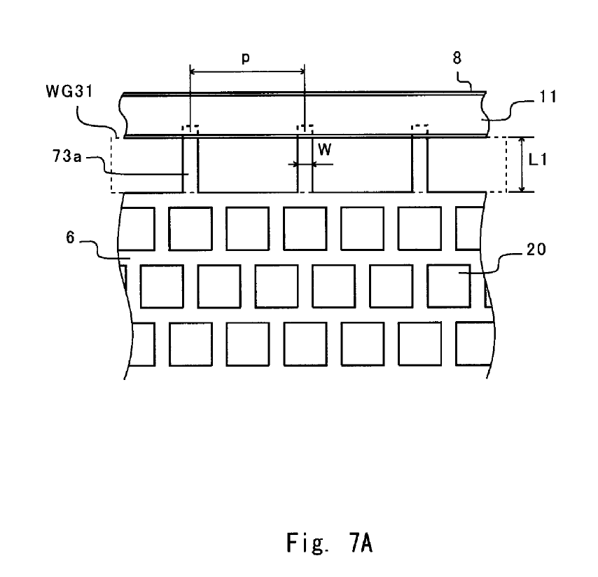

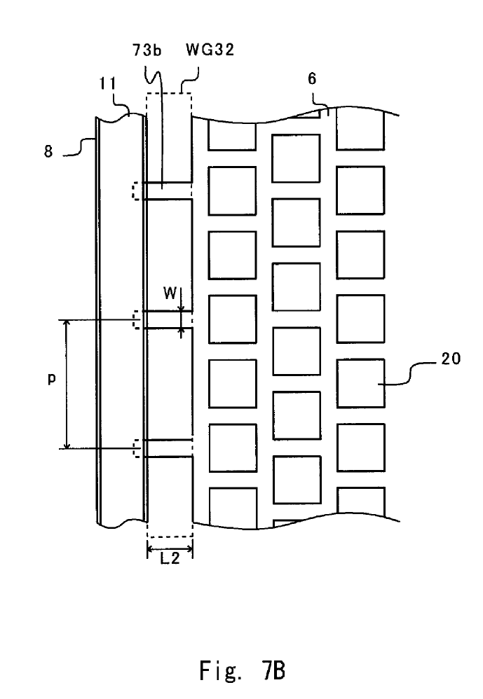

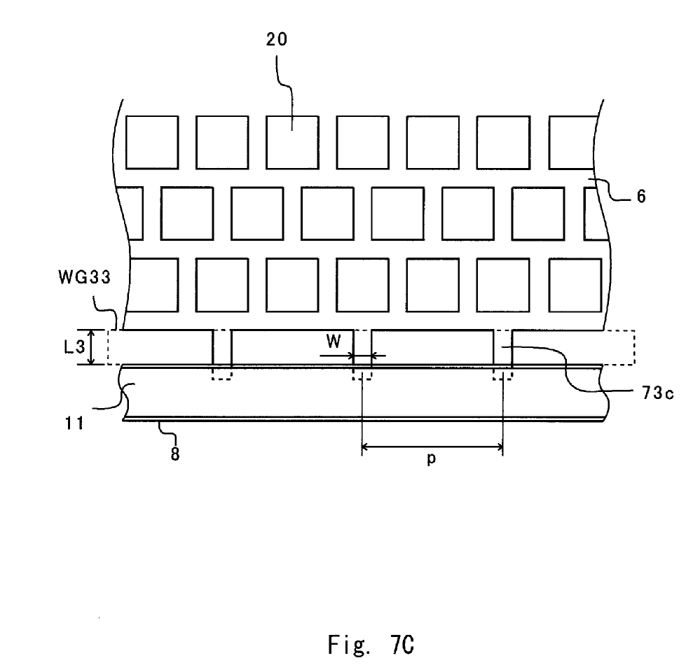

FIG. 7A is a top view of a region E31 shown in FIG. 6. Referring to FIG. 7A, in the gate lead-out line group WG31, gate lead-out lines 73a are formed with the arrangement pitch p, the width W, and a length L1. The other configurations are similar to those shown in FIG. 2A, so the description thereof is omitted.

FIG. 7B is a top view of a region E32 shown in FIG. 6. Referring to FIG. 7B, in the gate lead-out line group WG32, gate lead-out lines 73b are formed with a length L2. The other configurations are similar to those shown in FIG. 7A, so the description thereof is omitted.

FIG. 7C is a top view of a region E33 shown in FIG. 6. Referring to FIG. 7C, in the gate lead-out line group WG33, gate lead-out lines 73c are formed with a length L3. The other configurations are similar to those shown in FIG. 7A, and the description thereof is omitted.

In order to lower the electrical resistance, impurities are introduced into the gate electrode 6, the gate lead-out lines 73a to 73c, and the gate connection line 8 with the impurity concentration D.

In this configuration, the gate lead-out lines 73a to 73c have a uniform arrangement pitch p, a uniform width W, and a uniform impurity concentration D, while the lengths L1 to L3 in the gate lead-out line groups WG31 to WG33 differ from each other and are set to satisfy L1>L2>L3. Specifically, in this configuration, L1:L2:L3=4:3:2 is satisfied.

Here, consideration is given to a wiring resistance in the outer peripheral region of the semiconductor device. As in the first exemplary embodiment, the contribution of the gate connection line 8 to the wiring resistance in the gate lead-out line groups WG31 to WG33 is represented as (gate lead-out line group WG31)<(gate lead-out line group WG32)<(gate lead-out line group WG33).

Meanwhile, as the gate lead-out line groups are located farther away from the gate pad GP1, the lengths of the gate lead-out lines 73a to 73c in the gate lead-out line groups decrease and the electrical resistance decreases. Accordingly, the contribution of the gate lead-out lines 73a to 73c is represented as (gate lead-out line group WG31)>(gate lead-out line group WG32)>(gate lead-out line group WG33).

In other words, the magnitude relation between the contribution of the gate lead-out lines 73a to 73c and the contribution of the gate connection line 8 to the wiring resistance in the gate lead-out line groups WG31 to WG33 is reversed. Therefore, the difference in wiring resistance between paths in the gate lead-out line groups WG31 to WG33 can be reduced as compared with the case in which the gate lead-out lines 73a to 73c are formed with a uniform length. As a result, the gate voltage supplied to the gate pad GP1 can be more uniformly applied to the MOSFET cells 20 formed in the active region.

### Fourth Exemplary Embodiment

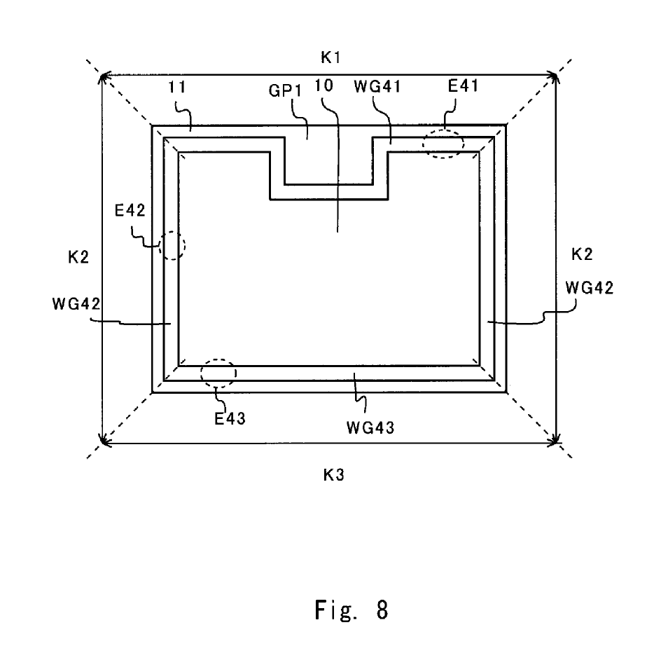

Next, the configuration of a semiconductor device according to a fourth exemplary embodiment of the present invention will be described. FIG. 8 is a top view showing the semiconductor device. Referring to FIG. 8, gate lead-out line groups WG41 to WG43 are formed between the source electrode 10 and the gate metal line 11. The other configurations are similar to those shown in FIG. 1, so the description thereof is omitted.

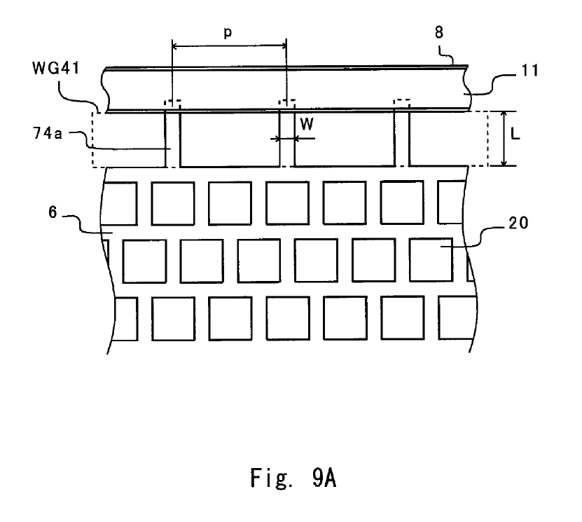

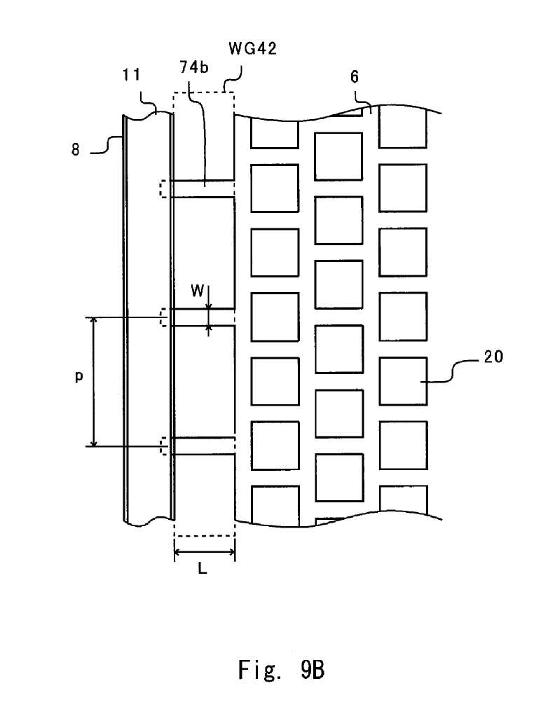

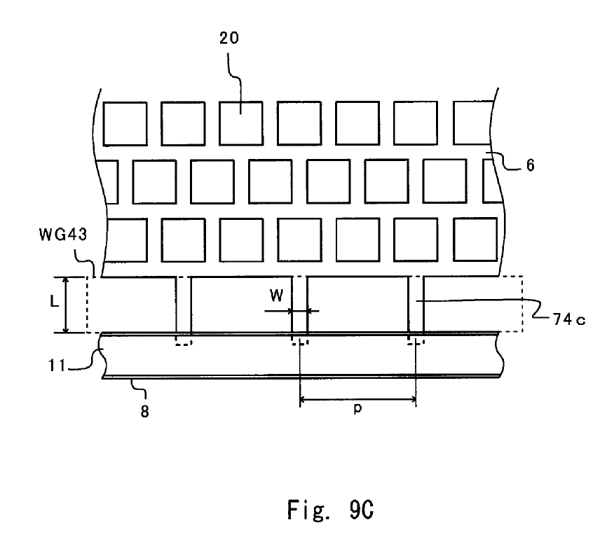

FIG. 9A is a top view of a region E41 shown in FIG. 8. Referring to FIG. 9A, in the gate lead-out line group WG41, gate lead-out lines 74a are formed with the arrangement pitch p, the width W, and the length L. In order to lower the electrical resistance of the gate lead-out lines 74a, impurities are introduced into the gate lead-out lines 74a with an impurity concentration D1. The other configurations are similar to those shown in FIG. 2A, so the description thereof is omitted.

FIG. 9B is a top view of a region E42 shown in FIG. 8. Referring to FIG. 9B, in the gate lead-out line group WG42, gate lead-out lines 74b are formed with the arrangement pitch p, the width W, and the length L. In order to lower the electrical resistance, impurities are introduced into the gate lead-out lines 74b with an impurity concentration D2. The other configurations are similar to those shown in FIG. 9A, so the description thereof is omitted.

FIG. 9C is a top view of a region E43 shown in FIG. 8. Referring to FIG. 9C, in the gate lead-out line group WG43, gate lead-out lines 74c are formed with the arrangement pitch p, the width W, and the length L. In order to lower the electrical resistance, impurities are introduced into the gate lead-out line 74c with an impurity concentration of D3. The other configurations are similar to those shown in FIG. 9A, so the description thereof is omitted.

In this configuration, the gate lead-out lines 74a to 74c have a uniform arrangement pitch p, a uniform width W, and a uniform length L, while the impurity concentrations D1 to D3 in the gate lead-out line groups WG41 to WG43 differ from each other and are set to satisfy D1<D2<D3.

In order to lower the electrical resistance, impurities are introduced into the gate electrode 6 and the gate connection line 8 with the impurity concentration D.

Here, consideration is given to a wiring resistance in the outer peripheral region of the semiconductor device. As in the first exemplary embodiment, the contribution of the gate connection line 8 to the wiring resistance in the gate lead-out line groups W41 to W43 is represented as (gate lead-out line group WG41)<(gate lead-out line group WG42)<(gate lead-out line group WG43).

Meanwhile, as the gate lead-out line groups are located away from the gate pad GP1, the impurity concentrations of the gate lead-out lines 74a to 74c in the gate lead-out line groups increase and the electrical resistance decreases. Accordingly, the contribution of the gate lead-out lines 74a to 74c in the gate lead-out line groups WG41 to WG43 is represented as (gate lead-out line group WG41)>(gate lead-out line group WG42)>(gate lead-out line group WG43).

In other words, the magnitude relation between the contribution of the gate lead-out lines 74a to 74c and the contribution of the gate connection line 8 to the wiring resistance in the gate lead-out line groups WG41 to WG43 is reversed. Therefore, the difference in wiring resistance between paths in the gate lead-out line groups WG41 to WG43 can be reduced as compared with the case in which the gate lead-out lines 74a to 74c are formed with a uniform impurity concentration. As a result, the gate voltage supplied to the gate pad GP1 can be more uniformly applied to the MOSFET cells 20 formed in the active region.

### Other Exemplary Embodiments

Note that the present invention is not limited to the above exemplary embodiments, but may be modified in various ways without departing from the scope of the present invention. For example, the semiconductor conductivity types employed in the above exemplary embodiments may be reversed.

While silicon is used as a semiconductor in the above exemplary embodiments, the semiconductor for use in the present invention is not limited thereto. For example, InP-based material, GaN-based material, or GaAs-based material may be used.

The dimensions such as the arrangement pitch, width, and length of the gate lead-out lines in the first to third exemplary embodiments are not limited to those described in the exemplary embodiments. Other dimensions may be used as long as the magnitude relation is maintained.

The elements to be arranged in the active region are not limited to MOSFETs having a trench gate structure. Any transistors having another structure may be used as long as the transistors can be integrated into a semiconductor device.

The outer peripheral region is not necessarily divided into three sections, but may be divided into an arbitrary number of sections. Moreover, dividing positions may be arbitrarily set.

In the above exemplary embodiments, the arrangement pitch, width, length, or impurity concentration of the gate lead-out lines is varied stepwise for each section, but ultimately, the arrangement pitch, length, or width of the gate lead-out lines may be varied geometrically according to a wiring distance from the gate pad GP1.

The arrangement pitch, width, length, and impurity concentration of the gate lead-out lines may be arbitrarily combined and changed. For example, the arrangement pitch of the gate lead-out lines may be varied for each gate lead-out line group, and the width of every gate lead-out line or every plural gate lead-out lines, which are formed in the gate lead-out line groups, may be varied. Alternatively, the length or impurity concentration thereof may be varied.

For example, the width of the gate lead-out lines may be varied for each gate lead-out line group, and the arrangement pitch of every gate lead-out line or every plural gate lead-out lines, which are formed in the gate lead-out line groups, may be varied. Alternatively, the length or impurity concentration thereof may be varied.

For example, the length of the gate lead-out lines may be varied for each gate lead-out line group, and the arrangement pitch of every gate lead-out line or every plural gate lead-out lines, which are formed in the gate lead-out line groups, may be varied. Alternatively, the width or impurity concentration thereof may be varied.

For example, the impurity concentration of the gate lead-out lines may be varied for each gate lead-out line group, and the arrangement pitch of every gate lead-out line or every plural gate lead-out lines, which are formed in the gate lead-out line groups, may be varied. Alternatively, the width or length thereof may be varied.

Furthermore, for example, the arrangement pitch and width of the gate lead-out lines may be varied geometrically or arithmetically according to the wiring distance from the gate pad GP1. Moreover, the arrangement pitch and length, the arrangement pitch and impurity concentration, the width and length, the width and impurity concentration, and the length and impurity concentration may be varied geometrically or arithmetically.

The first to fourth exemplary embodiments can be combined as desirable by one of ordinary skill in the art.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. A semiconductor device comprising:
a gate pad supplied with a gate voltage applied to a gate electrode of a field-effect transistor disposed in an active region;
a gate connection line connected to the gate pad; and
a plurality of gate lead-out lines connected in parallel between the gate electrode and the gate connection line,
wherein each of the plurality of gate lead-out lines has a resistance value that becomes smaller by every one or plural gate lead-out lines as the gate lead-out lines are located farther away from the gate pad.

2. The semiconductor device according to claim 1, wherein the gate pad, the gate connection line, and the gate lead-out lines are made of polysilicon.

3. The semiconductor device according to claim 2, wherein impurities are introduced into the gate pad, the gate connection line, and the gate lead-out lines.

4. The semiconductor device according to claim 1, wherein the gate lead-out lines are formed at a higher density as the gate lead-out lines are located farther away from the gate pad.

5. The semiconductor device according to claim 1, wherein the gate lead-out lines have a larger width as the gate lead-out lines are located farther away from the gate pad.

6. The semiconductor device according to claim 1, wherein the gate lead-out lines have a smaller length as the gate lead-out lines are located farther away from the gate pad.

7. The semiconductor device according to claim 3, wherein the impurities introduced into the gate lead-out lines increase in concentration as the gate lead-out lines are located farther away from the gate pad.

8. The semiconductor device according to claim 1, the semiconductor device being fabricated on a semiconductor substrate made of silicon.

9. The semiconductor device according to claim 1, wherein the field-effect transistor is a MOSFET.
